(19) United States
(12) Patent Application Publication
(10) Pub. No.: US 2015/0361577 A1
(43) Pub. Date: Dec. 17, 2015

(54) METHOD OF CASTING INGOT AND CONTAINING DEVICE OF INGOT CASTING FURNACE FOR CONTAINING MATERIALS OF INGOT

(71) Applicant: Sino-American Silicon Products lnc., Hsinchu (TW)

(72) Inventors: Hung-Sheng CHOU, Hsinchu (TW); Kuo-Wei Chuang, Hsinchu (TW); Yu-Min Yang, Hsinchu (TW); Wen-Huai Yu, Hsinchu (TW); Sung-Lin Hsu, Hsinchu (TW); Wen-Ching Hsu, Hsinchu (TW)

(21) Appl. No.: 14/732,962

(22) Filed: Jun. 8, 2015

Related U.S. Application Data
(60) Provisional application No. 62/012,810, filed on Jun. 16, 2014.

(51) Int. Cl. C30B 11/00; F27B 14/10; C30B 29/06; C30B 11/02

(52) U.S. Cl. CPC C30B 11/002; C30B 11/02; F27B 14/10; C30B 29/06

(57) ABSTRACT

A method of casting an ingot includes the following steps: place solid silicon raw materials on a bottom of a containing device, wherein the containing device includes a container and a graphite layer provided on a surrounding wall and an inner bottom of the container, and the solid silicon raw materials are stacked upon the graphite layer on the inner bottom; heat the container to melt the solid silicon raw material into liquid state; cool the container from the bottom up till all of the silicon raw materials are crystallized and solidified. The solidified silicon raw materials become an ingot. Whereby, the graphite layer can effectively prevent impurities of the container from contaminating the ingot.

This application claims the priority benefit of U.S. application 62/012,810, filed on Jun. 16, 2014. The entirety of the above-mentioned patent application is hereby incorporated by reference herein and made a part of this specification.

### BACKGROUND OF THE INVENTION

1. Technical Field

The present invention relates generally to ingot casting, and more particularly to a method of casting an ingot and a containing device of ingot casting furnace for containing materials of an ingot.

2. Description of Related Art

Solar energy is one of the most clean inexhaustible energy sources. To satisfy the increasing demand of solar cells and to lower the manufacturing cost, the wafers used in solar cells are mostly made of ingots which are mass produced by directional solidification method. In more details, directional solidification method is to load silicon raw materials into a crucible, and then to heat the crucible to melt the silicon raw materials. The temperature gradient of cooling is controlled to crystallize and solidify the melted silicon raw materials upwards from an inner bottom of the crucible. The silicon raw materials become an ingot after being solidified. After that, the ingot is demoulded to be eventually sliced into wafers that can be used in solar cells.

In order to facilitate the demoulding of ingots, the inner wall of a crucible is typically applied with a barrier layer to prevent impurities of the crucible from contaminating the melted silicon raw materials, and therefore the “red zone” on lateral sides of an ingot can be reduced in this way. Here the “red zone” refers to a part of an ingot which has a relatively lower lifetime, wherein lifetime is defined as the average time interval between generation and recombination of the minority carriers in a semi-conductor. China Patent No. CN103469303 discloses a method of providing a barrier layer on the inner lateral wall or the inner bottom of a crucible by spray coating or brush coating, and a sintered carbon layer is formed by sintering the barrier layer. China Patent NO. CN202913087U also discloses a method of providing an intermediate layer made of silicon nitride, which is further provided with high purified quartz sands thereon by spray coating, brush coating, or roll coating, on the inner lateral wall and the inner bottom of a crucible, and the intermediate layer and quartz sands are then sintered to form a composite layer.

The methods disclosed in the aforementioned patents can reduce the red zone of an ingot. However, making a barrier layer by coating tends to cause uneven thickness. As a result, there might be partial of a barrier layer happens to be too thin to effectively block out impurities of the crucible. If a barrier layer is not stacked tightly enough, or fails to provide sufficient bonding force, it may partially fall out while moving the crucible or placing silicon raw materials into the crucible, which apparently weakens the effect of preventing the diffusion of impurities. In addition, if a barrier layer contains too much carbon, impurities inside the barrier layer may be separated out, and the yield of products may be lowered consequently. If the particles of a barrier layer are too big, the produced ingots tend to have cracks due to the lattices of silicon materials or the mismatch between thermal expansion coefficients. Furthermore, since a barrier layer is merely attached on a crucible, it may become thinner with more demoulding processes being performed, and even be peeled off from the crucible.

### BRIEF SUMMARY OF THE INVENTION

In view of the above, the primary objective of the present invention is to provide a containing device of an ingot casting furnace and a method of casting an ingot, which effectively prevent impurities of a crucible from contaminating the cast ingot.

The present invention provides a containing device of an ingot casting furnace for containing materials, wherein the containing device includes a container and a graphite layer. The container has a surrounding wall and an inner bottom therein, wherein the surrounding wall and the inner bottom together form a housing tank which has an opening at a top thereof; the graphite layer is formed by laying a graphite material on the surrounding wall and the inner bottom of the container.

The present invention further provides a method of casting an ingot, which includes the following steps: A. lay a graphite layer upon a surrounding wall and an inner bottom of a container; B. load solid silicon raw materials into the container, and put the solid silicon raw materials on the graphite layer on the inner bottom of the container; C. heat the container to melt the silicon raw materials into liquid state; D. cool the container from a bottom up to crystallize and solidify the silicon raw materials from a bottom up till all of the silicon raw materials are crystallized and solidified, wherein the solidified silicon raw materials become an ingot.

Whereby, with the graphite layer as a barrier layer, the problem of uneven coating and abrasion which happen on a barrier layer can be effectively improved. Furthermore, since the melting point of graphite is higher than that of silicon, the graphite layer is able to maintain its original structure under a high temperature condition, and therefore impurities of the crucible would not easily diffuse into the melted silicon raw materials.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic diagram of the containing device of the ingot casting furnace of a first preferred embodiment of the present invention;

FIG. 2 is a top view of the containing device of the first preferred embodiment of the present invention;

FIG. 3 is a partial enlarged view of the containing device of the first preferred embodiment of the present invention;

FIG. 4 is a schematic diagram showing the plates abutting the graphite papers against the inner walls;

FIG. 5 is a schematic diagram of the containing device and the heating device;

FIG. 6 is a schematic diagram of a semi-finished ingot casted with the method of casting ingot;

FIG. 7 is a lifetime mapping graph of a lateral side of the ingot which is casted with the method of casting ingot;

FIG. 8 is a lifetime mapping graph of an ingot of the control group;

FIG. 9 is a Fe—B linescan graph of the wafers sliced from the bottom part of the connecting portion between two lateral walls of the ingot of the present invention and the ingot of the control group;

FIG. 10 is a Fe—B linescan graph of the wafers sliced from the middle part of the connecting portion between two lateral walls of the ingot of the present invention and the ingot of the control group;

FIG. 11 is a Fe—B linescan graph of the wafers sliced from the top part of the connecting portion between two lateral walls of the ingot of the present invention and the ingot of the control group;

FIG. 12 is a Fe—B linescan graph of the wafers sliced from the bottom part of the central portion of the ingot of the present invention and the ingot of the control group;

FIG. 13 is a Fe—B linescan graph of the wafers sliced from the middle part of the central portion of the ingot of the present invention and the ingot of the control group;

FIG. 14 is a Fe—B linescan graph of the wafers sliced from the top part of the central portion of the ingot of the present invention and the ingot of the control group;

FIG. 15 is an oxygen content distribution graph of the ingot of the present invention and the ingot of the control group;

FIG. 16 is a carbon content distribution graph of the ingot of the present invention and the ingot of the control group; and

FIG. 17 is a schematic diagram showing that the containing device of the first preferred embodiment is used to contain the silicon raw materials for the method of casting an ingot of a second preferred embodiment.

### DETAILED DESCRIPTION OF THE INVENTION

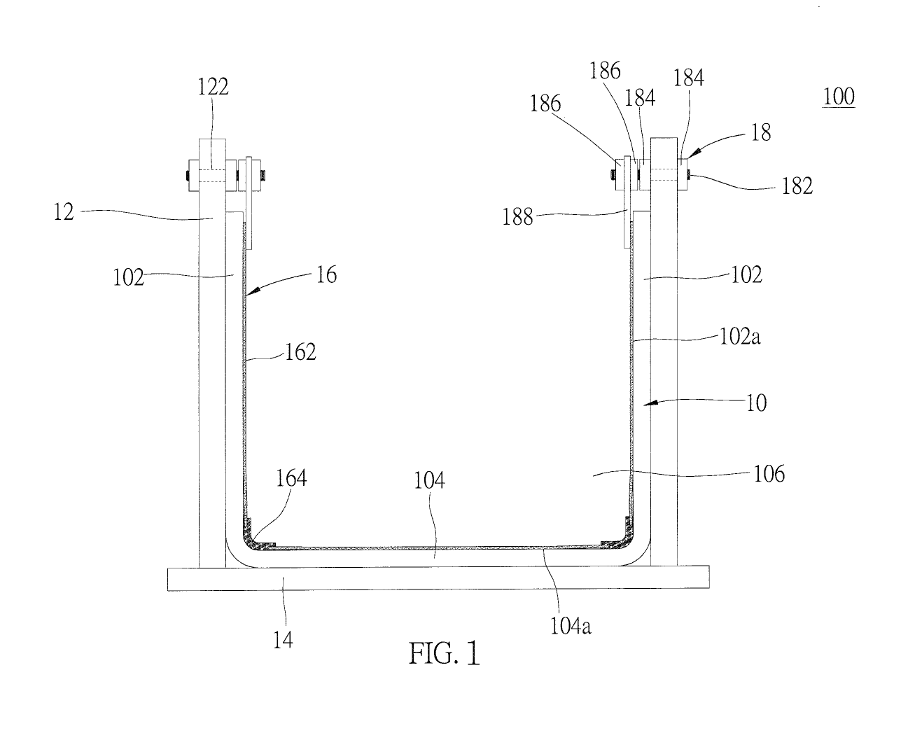

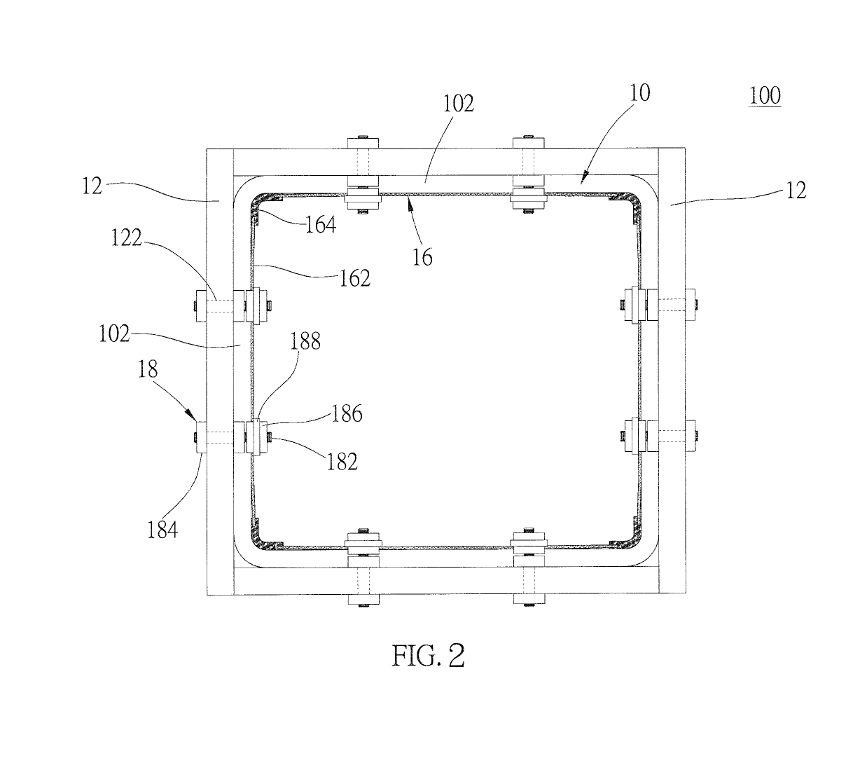

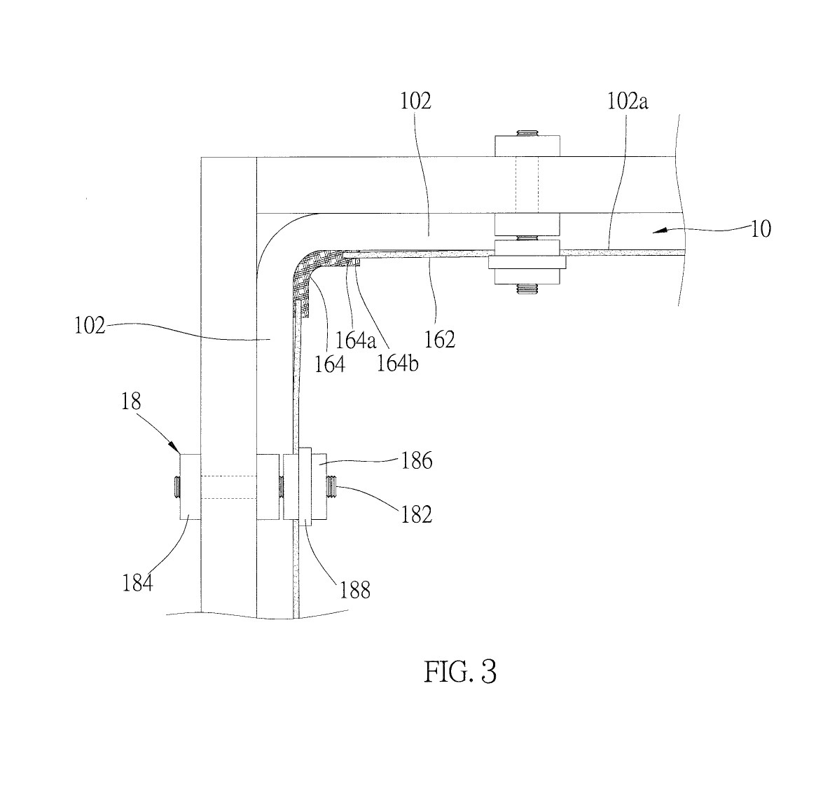

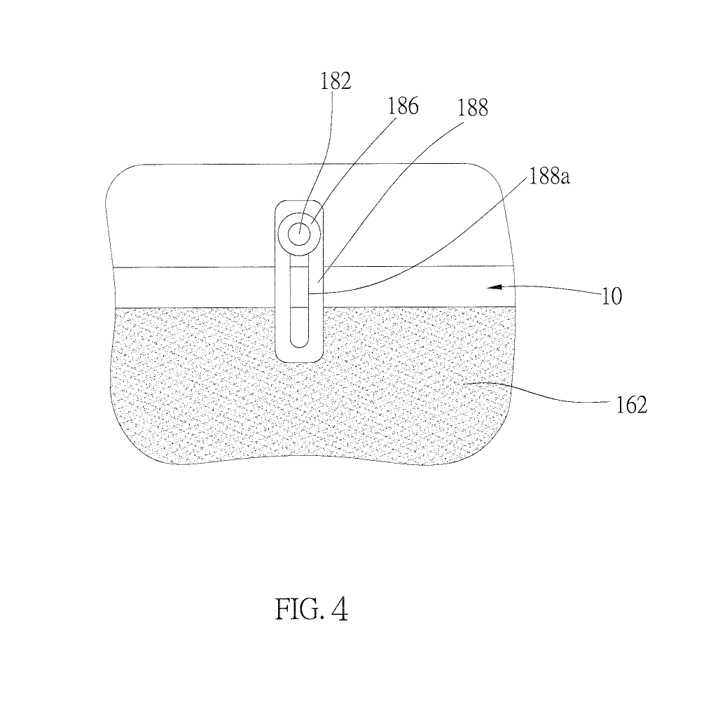

As shown in FIG. 1 to FIG. 4, a containing device 100 of an ingot casting furnace of a first preferred embodiment of the present invention includes a container, a graphite layer 16, and a plurality of grippers 18, wherein the container is a crucible 10 in the first preferred embodiment.

The crucible 10 is integrally composed of four lateral walls 102 and a floor 104, wherein the four lateral walls 102 and the floor 104 together form a housing tank 106 which has an opening at a top thereof, and the housing tank 106 is used for housing raw materials. The inner surfaces 102a of the four lateral walls 102 forms a surrounding wall inside the crucible 10, and top surface 104a of the floor 104 forms an inner bottom inside the crucible 10. In practice, the crucible 10 can be a cylinder or have a shape of polygons, and the surrounding wall would be circular or polygonal in such cases. Outer peripheries of the four lateral walls 102 of the crucible 10 are respectively provided with a first holding board 12, and an outer periphery of the floor 104 is provided with a second holding board 14. The first and the second holding boards 12, 14, which are made of graphite material, form an outer crucible together, wherein the outer crucible abuts against an outer surface of the crucible 10 to firmly support the crucible 10. A top margin of each of the first holding boards 12 is higher than a top margin of each of the lateral walls 102. Each of the first holding boards 12 is provided with two perforations 122 at where higher than the top margin of the corresponding lateral wall 102, wherein the perforations 122 on each of the first holding boards 12 are separated with a distance.

The graphite layer 16 includes a plurality of graphite papers 162 and a plurality of graphite fixers 164. A thickness of the graphite papers 162 is between 0.2 and 1 mm, and is preferred to be between 0.4 and 0.8 mm. The graphite papers 162 are attached on the inner surfaces 102a of the lateral walls 102 and the top surface 104a of the floor 104. Each of the graphite papers neighbors at least one of the other graphite papers, and lateral margins of each two neighboring graphite papers 162 are separated with a distance. Because connecting portions between each two neighboring lateral walls 102 and between the floor 104 and each of the lateral walls 102 inside the crucible 10 are all curved, and the flexibility of the graphite papers 162 is limited, the graphite fixers 164 are made of carbon fabric, which is more flexible, in the first preferred embodiment. Each of the graphite fixers 164 is provided along the lateral margins of two neighboring graphite papers 162, and is bent to fit the curve of the connecting portions between the lateral walls 102 inside the crucible 10. Some of the graphite fixers 164 are provided to the connecting portions between the floor 104 and each of the lateral walls 102 in the same way. Each of the graphite fixers 164 has two lateral sides 164a, each is provided with an insertion groove 164b, and each of the insertion grooves 164b is respectively inserted by the lateral margin of one of the graphite papers 162 to fill the distance between the lateral margins of two neighboring graphite papers 162. Whereby, the graphite layer 16 forms a barrier layer which can be removed from the housing tank 106 of the crucible 10. In practice, if the connecting portions between two neighboring lateral walls 102 and between the floor 104 and each of the lateral walls 102 are at right angles, the graphite fixers 164 can be omitted, and the lateral margins of two neighboring graphite papers 162 are connected to each other to form the barrier layer.

The grippers 18 are one securing means in the first preferred embodiments, wherein each of the grippers 18 includes a screw rod 182 made of graphite material, two first screw nuts 184, two second screw nuts 186, and a plate 188. Each of the screw rods 182 goes through one of the perforations 122 of one of the first holding boards 12. Take one of the grippers 18 for example, the two first screw nuts 184 are connected to the screw rod 182, and together grip an inner side and an outer side of one of the first holding boards 12, and therefore the screw rod 182 is fixed on the corresponding first holding board 12. The two second screw nuts 186 are connected to another end of the screw rod 182. The plate 188 has a slot 188a which is screwed by the screw rod 182. The plate 188 is between the two second screw nuts 186, and is gripped by the second screw nuts 186 to be fixed on the screw rod 182. The plate 188 abuts a part of the top margin of one of the graphite papers 162 against the corresponding inner surface 102a which the graphite paper 162 is laid on. Whereby, the grippers 18 can effectively fix the graphite papers 162 on the inner surfaces 102a of the crucible 10, and prevent the graphite papers 162 from falling down. The slot 188a of the plate 188 can protect the plate 188 from deformation or even break while being heated.

The securing means is not limited as the grippers 18 shown in the first preferred embodiment, any gripping structures that can fix the top margins of the graphite papers 162 on the lateral walls 102 of the crucible 10 can be used as the securing means in other embodiments. In addition, the securing means can be graphite paste which is able to stick the graphite papers 162 onto the inner surfaces 102a.

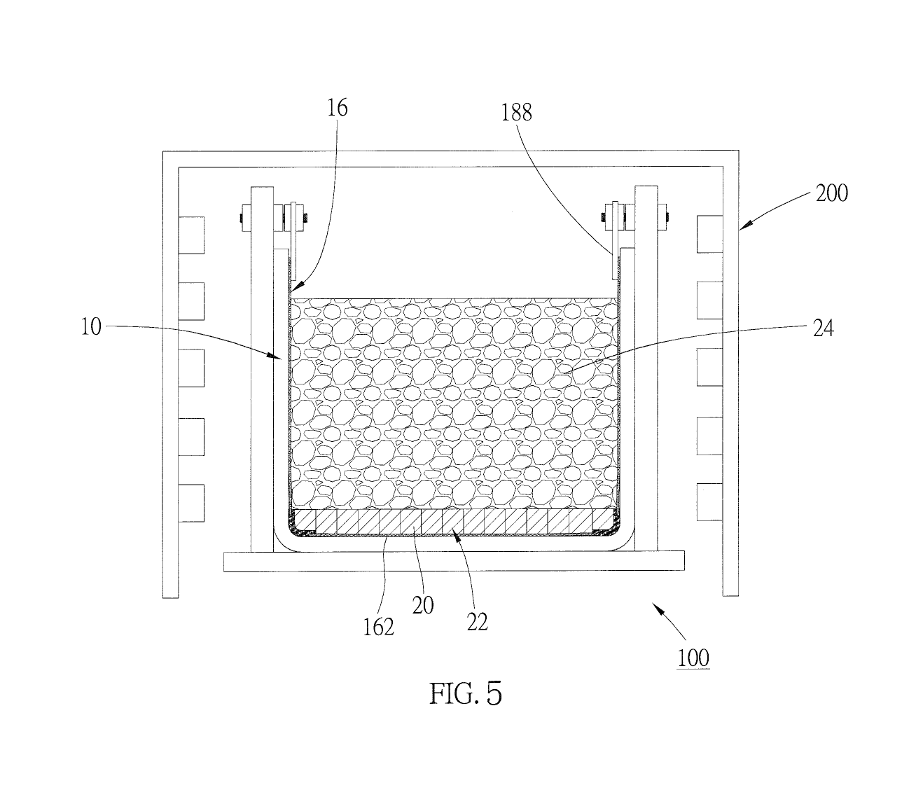

As shown in FIG. 5, after the graphite layer 16 is fixed inside the crucible 10, a plurality of seed crystals 20 are stacked upon the graphite paper 162 on the inner bottom of the crucible 10, wherein the seed crystals 20 are arranged to form a seed crystal layer 22. The crystal orientation of the seed crystal layer 22 can be in one or more than one direction, and the seed crystals 20 may be arranged tightly, or arranged with a space between each neighboring seed crystals 20. In practice, the seed crystals 20 can be chosen from monocrystal or polycrystal to meet different requirements. Solid silicon raw materials 24 are than loaded into the crucible 10, and they are stacked upon the seed crystal layer 22. A height of the stacked silicon raw materials 24 is preferred not to touch a bottom end of the plates 188. In this way, the melted silicon raw materials 24 would not be stuck with the plates 188 and the graphite papers 162.

After that, the containing device 100 which contains the seed crystals 20 and the silicon raw materials 24 is placed into the ingot casting furnace, wherein the heating device 200 of the ingot casting furnace is shown in FIG. 5. The heating device 200 is controlled to heat the crucible 10 to melt all of the silicon raw materials 24 inside the crucible 10 into liquid state. The heating process is stopped once a top portion of the seed crystal layer 22 starts to melt. A crystal growth step is then taken, wherein the heating device 200 is controlled to lower a temperature of the seed crystal layer 22 below a melting point thereof, and the seed crystal layer 22 is then crystallized and solidified gradually upwards. During the current step, an interface between solid and liquid silicon raw materials 24 is gradually rising as well, till all of the silicon raw materials 24 inside the crucible 10 are crystallized and solidified. The solidified silicon raw materials 24 become an ingot.

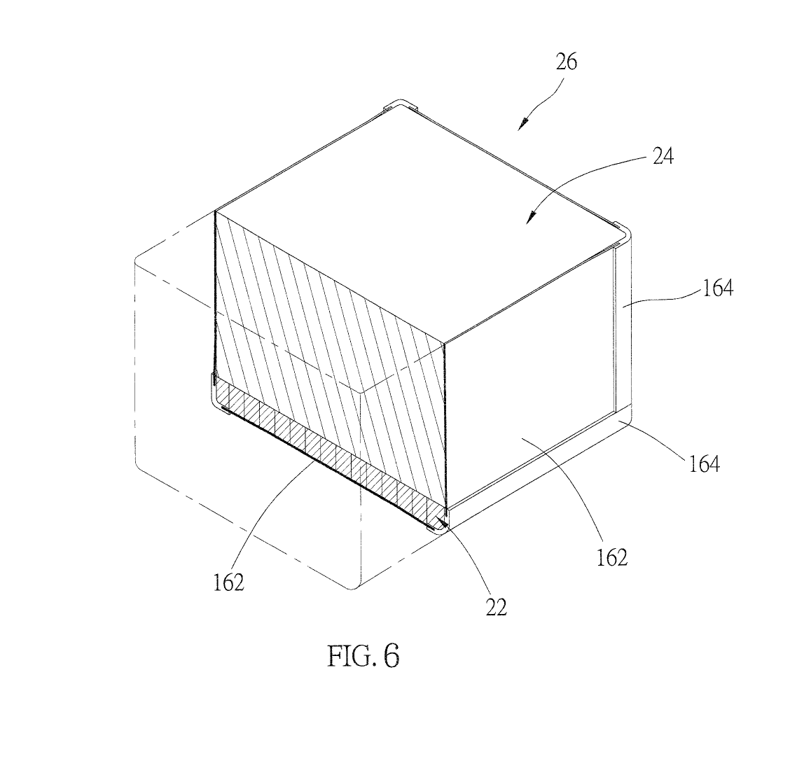

After cooling, the grippers 18 can be removed to proceed a demoulding procedure. As shown in FIG. 6, the demoulded semi-finished ingot 26 includes a main body 28 which is composed of the silicon raw materials 24, and a seed crystal layer 22 which is integrally connected to a bottom of the main body 28. The main body 28 has four lateral walls, each of which is respectively attached with one of the graphite papers 162. A bottom surface of the seed crystal layer 22 is also attached with one of the graphite papers 162. In addition, the connecting portion between each two neighboring lateral walls and between the bottom surface of the seed crystal layer and each of the lateral walls is respectively attached with one of the graphite fixers 164. The demoulding procedure of the semi-finished ingot 26 can be facilitated with the help of the graphite layer 16. The graphite papers 162 and the graphite fixers 164 are not only able to prevent impurities of the crucible 10 from contaminating the ingot, but also able to protect the main body 28 from being collided while being moved.

Eventually, the ingot can be obtained by removing the graphite layer 16 and the seed crystal layer 22 of the semi-finished ingot 26.

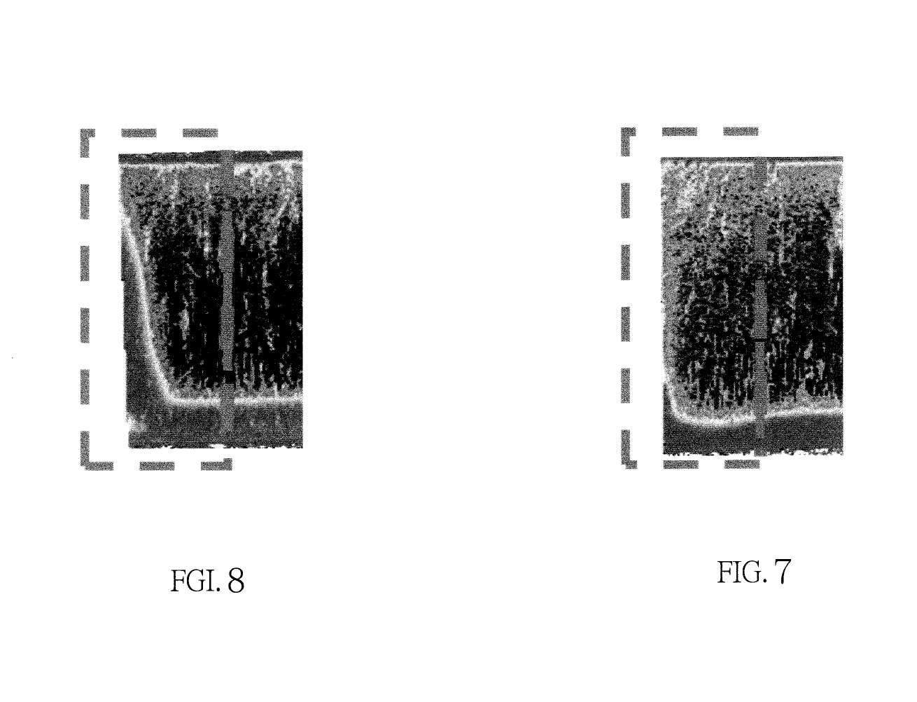

As previously described, FIG. 7 is a lifetime mapping graph of a lateral side of the ingot which is produced by the method of the present invention, and FIG. 8 is a lifetime mapping graph of an ingot of a control group. The method of casting an ingot of the control group is the same with the method of the present invention, except that the crucible 10 is not provided with the graphite layer 16 wherein. For convenience of explanation hereafter, ingot A represents the ingot produced by the method of the present invention, and ingot B represents the ingot of the control group.

As we can see at the dotted portion in FIG. 7 and FIG. 8, a red zone (a part of an ingot which has a relatively lower lifetime) on a lateral side of the ingot A is clearly smaller than that of the ingot B. A contaminated proportion on the lateral side of the ingot A is 0.45%, while a contaminated proportion on the lateral side of the ingot B is 7.06%. Therefore, the method of the present invention can effectively prevent the impurities of the crucible 10 from contaminating the ingot through the lateral side thereof.

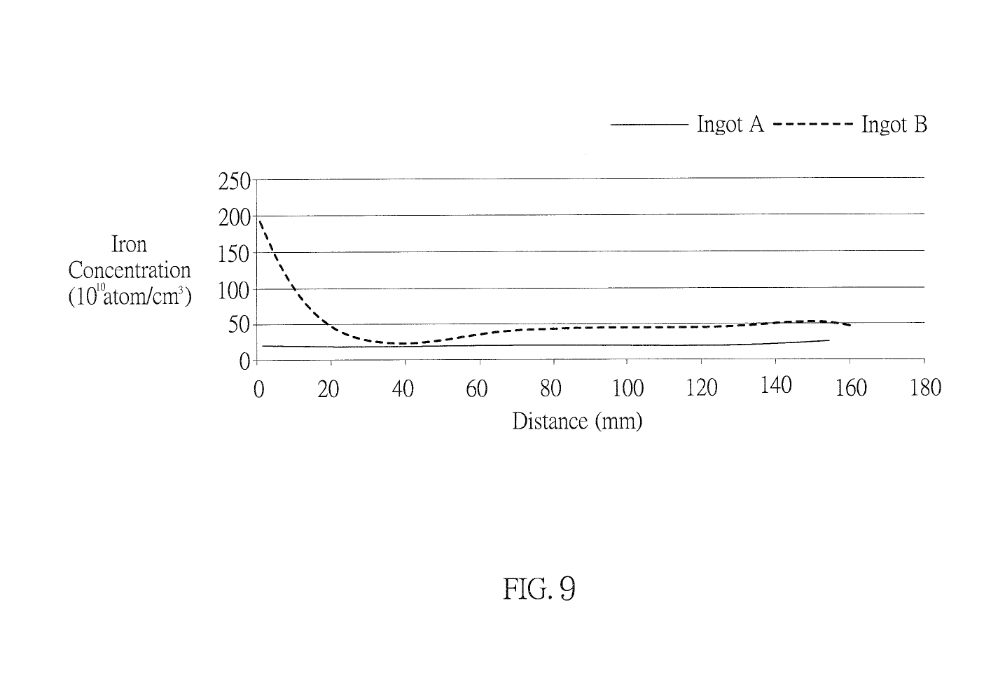

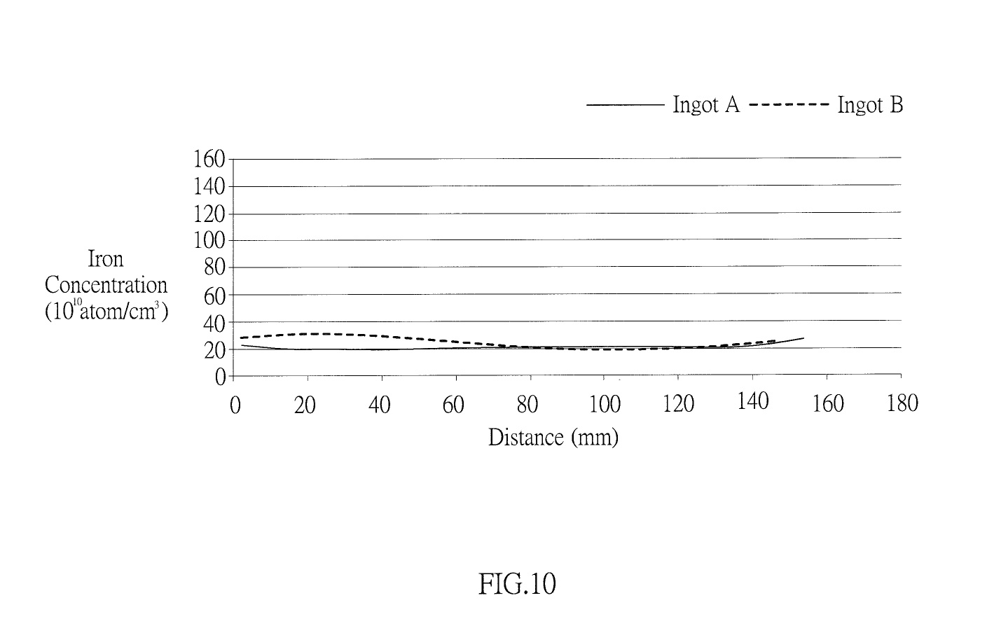

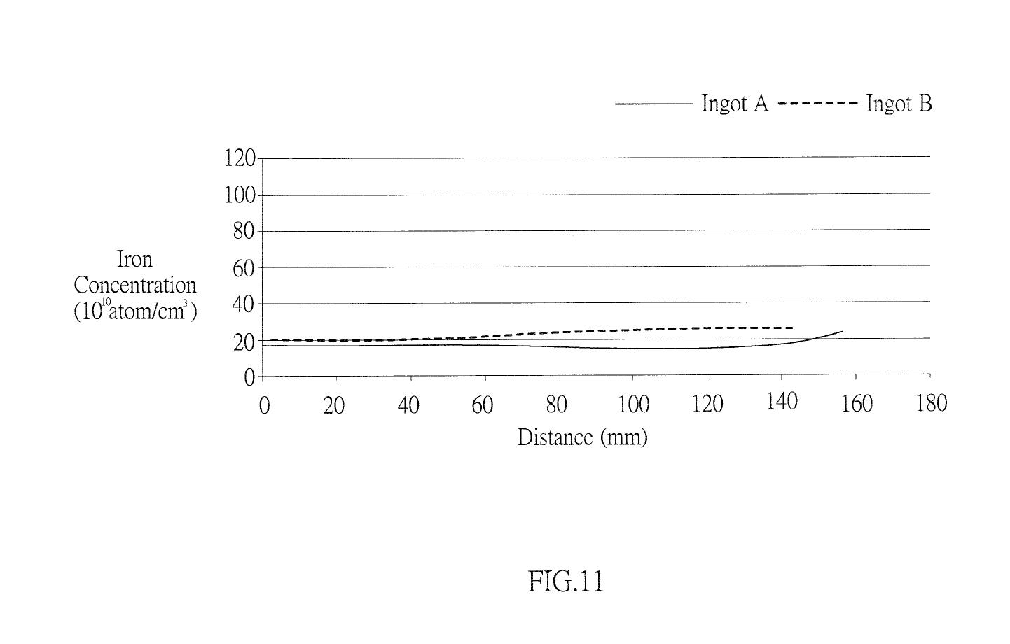

FIG. 9, FIG. 10, and FIG. 11 show Fe—B linescan graphs of wafers which are respectively sliced from a bottom portion, a middle portion, and a top portion of the connecting portion between two lateral walls of the ingot A and the ingot B. As shown in FIG. 9, an iron concentration of the wafers sliced from the bottom portion of the ingot A is apparently lower than that of the wafers sliced from the bottom portion of the ingot B, particularly at a portion near the lateral side (between 0 and 30 mm). As shown in FIG. 10 and FIG. 11, iron concentrations of the wafers sliced from the middle portion and the top portion of the ingot A are also apparently lower than that of the wafers sliced from the middle portion and the top portion of the ingot B. It can be seen that the graphite layer 16 provided in the present invention can indeed reduce the extent of diffusing impurities into the ingot, and the effect can be best seen in the wafers sliced from the bottom portion.

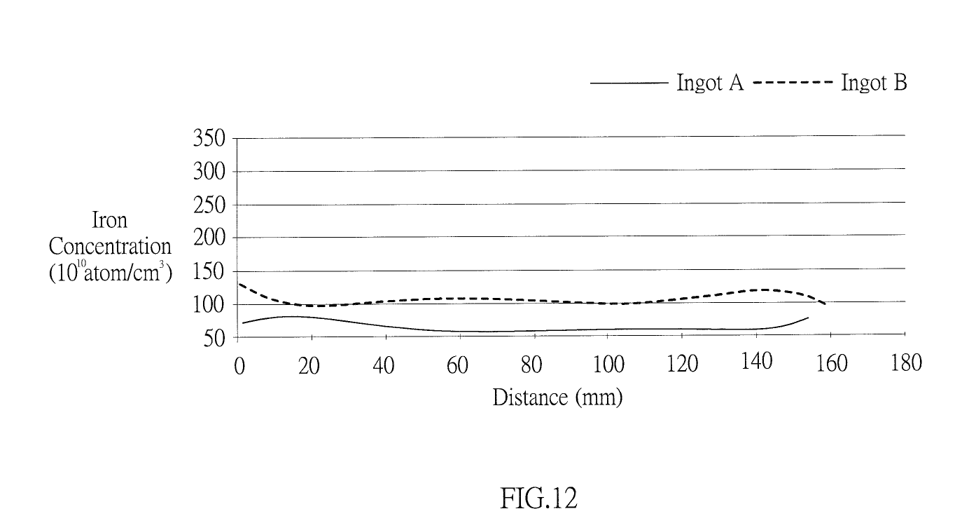

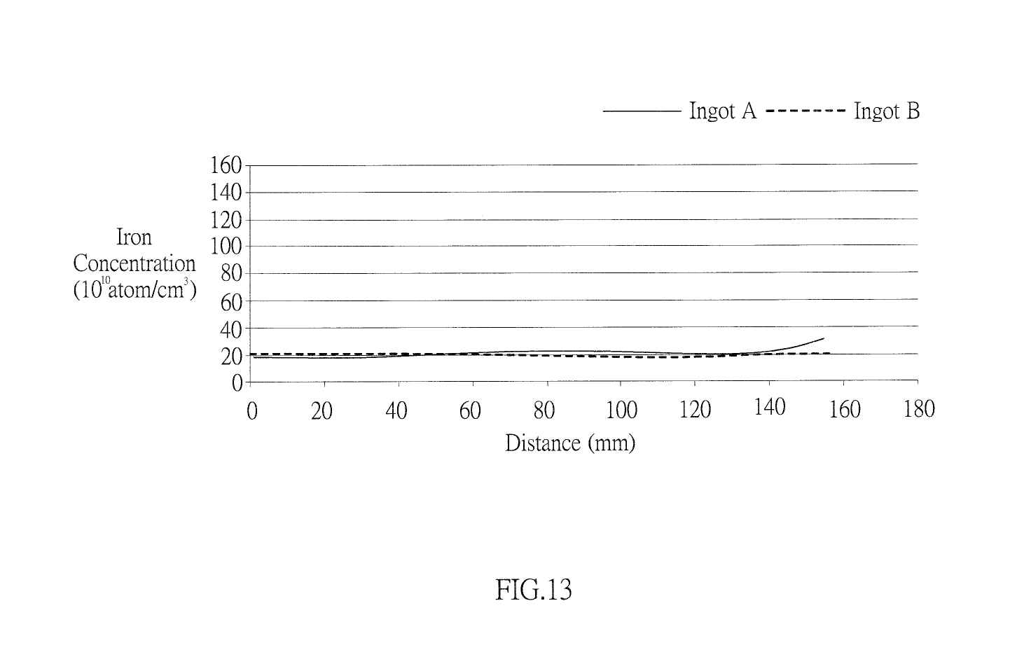

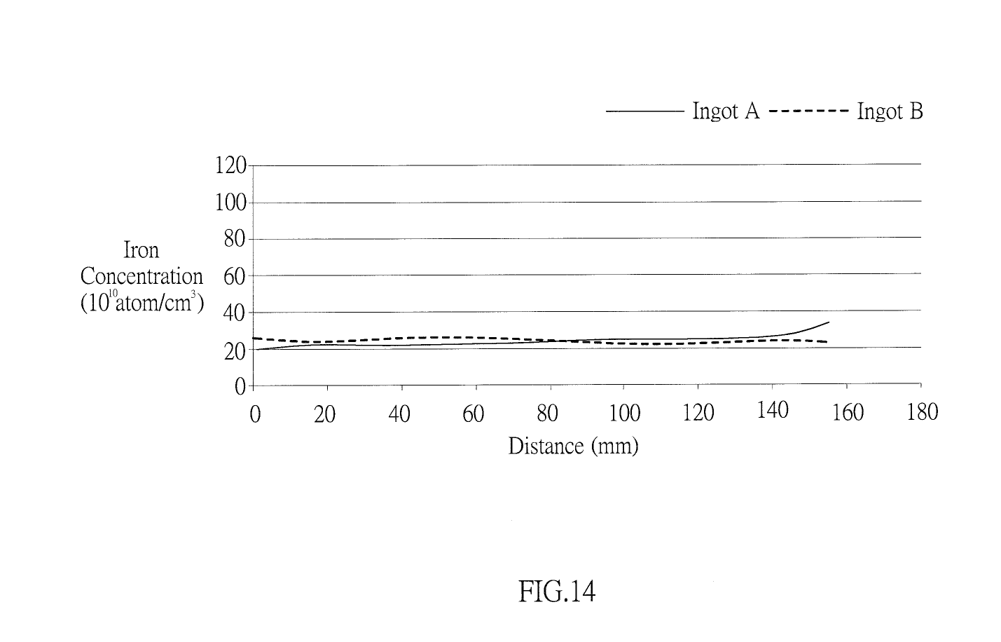

FIG. 12, FIG. 13, and FIG. 14 show Fe—B linescan graphs of wafers which are respectively sliced from a bottom portion, a middle portion, and a top portion of a central portion of the ingot A and the ingot B. As shown in FIG. 12, an iron concentration of the wafer sliced from the bottom portion of the ingot A is apparently lower than that of the bottom portion of the ingot B, too. As shown in FIG. 13 and FIG. 14, iron concentrations of the wafer sliced from the middle portion and the top portion of the ingot A are close to that of the middle portion and the top portion of the ingot B.

Average photoelectric conversion efficiencies of the solar cells which contain the wafers sliced from the bottom portion, the middle portion, and the top portion of the central portion of the ingot A and the ingot B are respectively 17.8% and 17.65%. In order words, the ingot produced by the method of the present invention has better performance than the ingot of the control group.

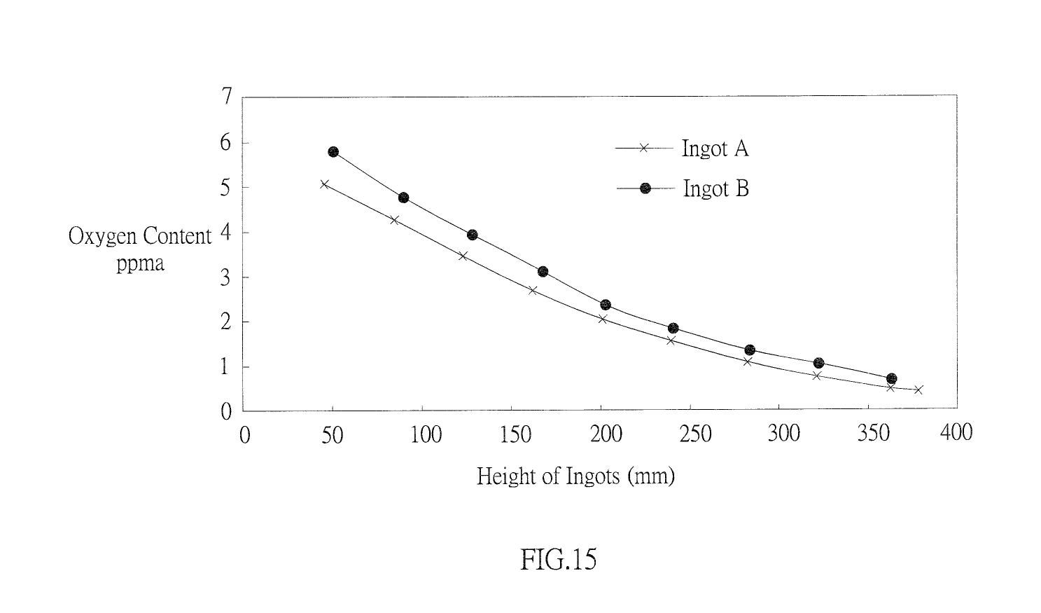

As shown in FIG. 15, average oxygen content of the ingot A is lower than that of the ingot B. Since oxygen content affects the photoelectric conversion efficiency and the light degeneration of solar cells, the performance of the ingot A is better than the ingot B.

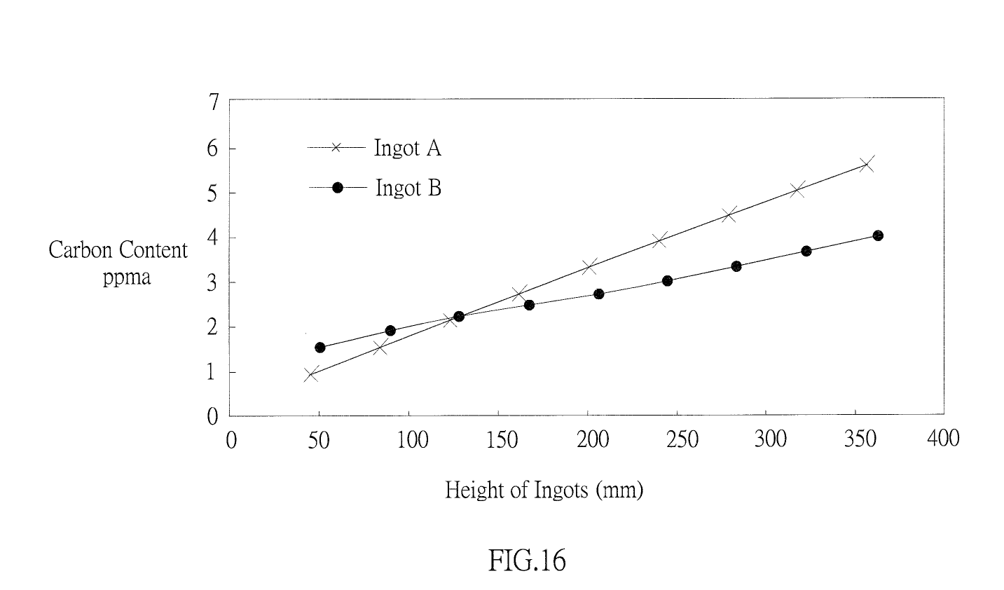

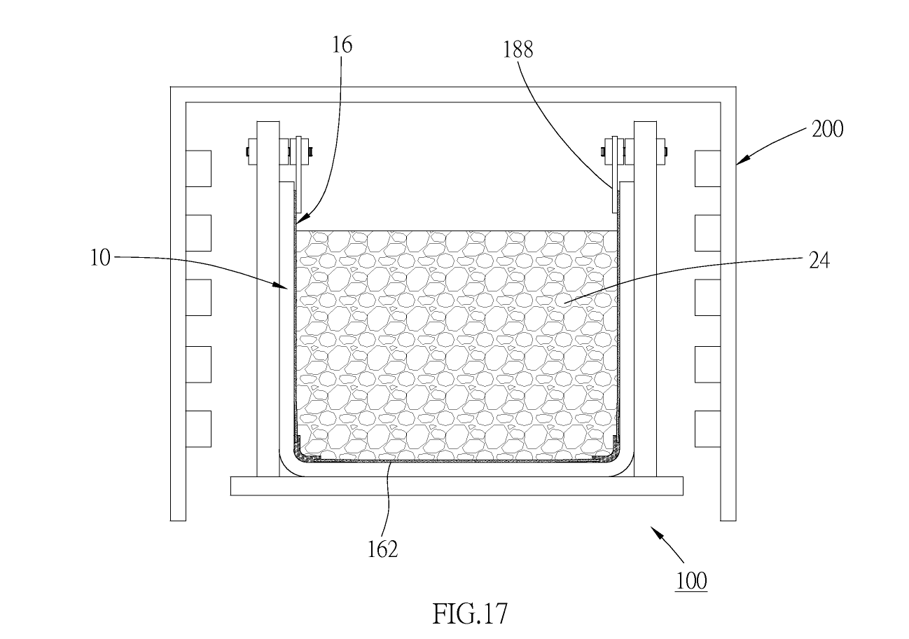

As shown in FIG. 16, average carbon content of the ingot A is higher than that of the ingot B. This is because the graphite layer 16 contacts the melted silicon raw materials 24, and a slight amount of carbon is released thereinto. Though the average carbon content of most parts of the ingot A is higher, the photoelectric conversion efficiency is not affected.

The first preferred embodiment described above casts ingots by using the seed crystal layer 22 for seeding, and a method of casting an ingot of a second preferred embodiment provided in the present invention also uses the containing device 100 of the first preferred embodiment. The method of the second preferred embodiment is roughly the same with the steps of the first preferred embodiment, except that, instead of using seed crystals for seeding, the silicon raw materials 24 are loaded into the crucible 10 and directly put on the graphite papers 162 on the bottom of the crucible 10. After that, the heating device 200 is controlled to melt all of the silicon raw materials 24, and then the heating device 200 is controlled again to gradually crystallize and solidify the melted silicon raw materials 24 from the bottom up till all of the silicon raw materials 24 are crystallized and solidified, wherein the solidified silicon raw materials 24 become an ingot.

In summary, the graphite layer 16 can effectively prevent the impurities of the crucible 10 from contaminating the ingot, and reduce the red zone thereof. Furthermore, high quality wafers can be obtained by slicing the ingot, and the photoelectric conversion efficiency of solar cells can be enhanced. It is worth mentioning that the graphite layer of the present invention can be removed from the crucible, and therefore the graphite layer is demoulded along with the ingot in every demoulding procedure. In this way, the container can be laid with a new graphite layer before next time of demoulding. Therefore, the problem of uneven coating, peeling off, and abrasion of the barrier layer can be effectively improved or even completely avoided.

It must be pointed out that the embodiments described above are only some preferred embodiments of the present invention. All equivalent structures and methods which employ the concepts disclosed in this specification and the appended claims should fall within the scope of the present invention.

What is claimed is:

1. A containing device of an ingot casting furnace for containing materials, comprising:
a container having a surrounding wall and an inner bottom therein, wherein the surrounding wall and the inner bottom together form a housing tank which has an opening at a top thereof; and
a graphite layer, which is formed by laying a graphite material on the surrounding wall and the inner bottom of the container.

2. The containing device of claim 1, wherein the graphite layer comprises a plurality of graphite papers, which are attached on the surrounding wall and the inner bottom; each of the graphite papers neighbors at least one of the other graphite papers, and each two neighboring graphite papers has their lateral margins connected together.

3. The containing device of claim 1, wherein the graphite layer comprises a plurality of graphite papers and at least one graphite fixer; the graphite papers are attached on the surrounding wall and the inner bottom, and each of the graphite papers neighbors at least one of the other graphite papers; lateral margins of each two neighboring graphite papers are separated with a distance; the at least one graphite fixer is provided along the lateral margins of two of the neighboring graphite papers.

4. The containing device of claim 3, wherein the at least one graphite fixer has two lateral side, and each of the lateral sides is provided with an insertion groove, in which one of the lateral margins of one of the graphite papers is inserted.

5. The containing device of claim 1, further comprising a securing means to secure the graphite layer inside the container.

6. The containing device of claim 5, wherein the securing means comprises a plurality of grippers provided along a top margin of the container; each of the grippers grips a part of the graphite layer which is near the top margin of the container.

7. The containing device of claim 6, wherein each of the grippers comprises a plate, which abuts the part of the graphite layer which is near the top margin of the container against the surrounding wall.

8. A method of casting an ingot, comprising the steps of:
A. laying a graphite layer upon a surrounding wall and an inner bottom of a container;
B. loading solid silicon raw materials into the container, and putting the solid silicon raw materials on the graphite layer on the inner bottom of the container;
C. heating the container to melt the silicon raw materials into liquid state; and
D. cooling the container from a bottom up to crystallize and solidify the melted silicon raw materials from a bottom up till all of the silicon raw materials are crystallized and solidified, wherein the solidified silicon raw materials become an ingot.

9. The method of claim 8, wherein the graphite layer comprises a plurality of graphite papers; the graphite papers are attached upon the surrounding wall and the inner bottom in step A, and each of the graphite papers neighbors at least one of the other graphite papers; lateral margins of each two neighboring graphite papers are connected together.

10. The method of claim 8, wherein the graphite layer comprises a plurality of graphite papers and at least one graphite fixer; the graphite papers are attached on the surrounding wall and the inner bottom in step A, and each of the graphite papers neighbors at least one of the other graphite papers, while the at least one graphite fixer is provided along lateral margins of two of the neighboring graphite papers.

11. The method of claim 8, further comprising a step of using a securing means to secure the graphite layer on the surrounding wall of the container after step A.

12. The method of claim 11, wherein the securing means comprises a plurality of grippers, which are separately provided along a top margin of the container; each of the grippers grips a part of the graphite layer which is near the top margin of the container.

13. The method of claim 12, wherein each of the grippers comprises a plate, which abut the part of the graphite layer which is near the top margin of the container against the surrounding wall.

14. The method of claim 8, further comprising the step of stacking a plurality of seed crystals on the graphite layer on the bottom of the container to form a seed crystal layer, wherein the solid silicon raw materials are stacked on the seed crystal layer in step B; the silicon raw material and a top of the seed crystal layer are melted into liquid state in step C; the melted silicon raw material is crystallized and solidified from the top of the seed crystal layer in step D.
